(19) United States
(12) Patent Application Publication
(10) Pub. No.: US 2008/0270856 A1
(43) Pub. Date: Oct. 30, 2008

(54) SEMICONDUCTOR MEMORY DEVICE

(75) Inventor: Koji MATSUBAYASHI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 11/867,019

(22) Filed: Oct. 4, 2007

(30) Foreign Application Priority Data
Oct. 5, 2006 (JP) 2006-274029

(51) Int. Cl. G01R 31/3177; G06F 11/25

(52) U.S. Cl. 714/726; 714/E11.155

(57) ABSTRACT

Malfunction of burn-in test caused by a failure of setting a determined test mode due to a “line defect” of the test is prevented. A semiconductor memory device having a logic unit including a control circuit C2 to control an output of an “on-chip compare” signal OCC indicating pass/fail of a data that is read from a memory array on the basis of a scan signal SCAN upon burn-in test. A specified terminal PAD from a plurality of terminals for power potential provided in the semiconductor memory device is used for the burn-in test. The logic unit comprises a control circuit C1 on an input path of the scan signal SCAN to control an output of the scan signal SCAN on the basis of a signal (VDD/OPEN) from the specified terminal PAD.

### REFERENCE TO RELATED APPLICATION

The present application is claiming the priority of the earlier Japanese patent application No. 2006-274029 filed on Oct. 5, 2006, the entire disclosure thereof being incorporated herein by reference thereto.

### FIELD OF THE INVENTION

This invention relates to a semiconductor memory device, and particularly relates to a semiconductor memory device that is effective at a burn-in test.

### BACKGROUND OF THE INVENTION

In fabrication steps of semiconductor memory devices, after sealing and packaging of the devices, a burn-in test (BT, TBT test) to weed out initial defective devices is performed as a screening step by applying heat and voltage stress to accelerate their deterioration. A semiconductor test device (tester) as described in Patent Document 1, for example, is used for the burn-in test. At the semiconductor test many of the semiconductor memory devices are tested on a burn-in board at once to save time. Each terminal of the semiconductor memory devices is in contact with a socket on the burn-in board.

Referring to FIG. 3, scan signals SCAN1 to SCANm, address signal ADD, command signal COM, clock signal CLK, initializing signal INIT, supply voltage VDD and ground potential GND, etc., are input to each of semiconductor memory devices D1 to Dm from the semiconductor test device (not shown). The scan signals SCAN1 to SCANm are input to corresponding semiconductor memory devices D1 to Dm of every column. The address signal ADD, command signal COM, clock signal CLK, initializing signal INIT, supply voltage VDD and ground potential GND, etc., are commonly input to the semiconductor memory devices D1 to Dm of every line. Output signals to the semiconductor test device (not shown) from the semiconductor memory devices D1 to Dm are commonly connected. A test performed in such a way is called an “on-chip compare” test.

Referring to FIG. 4, the input signals (scan signal SCAN, address signal ADD, command signal COM, clock signal CLK, initializing signal INIT, supply voltage VDD and ground potential GND, etc.) input in the semiconductor device D are input in a control portion. The control portion outputs the scan signal SCAN to a logic unit, the address signal ADD, command signal COM and clock signal CLK, etc., to a memory array, the initializing signal INIT to a second comparator and the supply voltage VDD and ground potential GND to each portion, respectively. The memory array reads a plurality of data DQ corresponding to the address signal ADD on the basis of the address signal ADD, command signal COM and clock signal CLK, etc., and outputs the data DQ to a first comparator. The first comparator compares each data DQ with an expected value, judges an agreement of them and outputs a plurality of flag signals FOUT indicating pass/fail (pass or fail) to the second comparator. The second comparator compresses each flag signal FOUT into one compressed data CD on the basis of the each flag signal and the initializing signal INIT, judges whether the compressed data CD is identical or not and then outputs an “on-chip compare” signal OCC indicating pass/fail to the logic unit (FIGS. 5A and 5B). The logic unit outputs an output signal on the basis of the scan signal SCAN, “on-chip compare” signal OCC, supply voltage VDD and ground potential GND to the semiconductor test device (not shown) (FIGS. 6A and 6B).

During the test for the semiconductor memory devices D1 to Dm, a line of which only one of the scan signal SCAN1 to SCANm is set “L” is tested and semiconductor memory devices of other lines are not tested. In a normal state, an output signal for only one semiconductor memory device (target device) is output because the scan signal SCAN for the one semiconductor memory device (target device) is “L” and the scan signals SCAN for other semiconductor memory devices (non-target devices) are “H” (FIG. 7A).

[Patent Document 1]

JP Patent Kokai Publication No. JP-A-10-19974

### SUMMARY OF THE DISCLOSURE

The entire disclosure of the above Patent Document 1 is incorporated herein by reference thereto. In the following, analysis is presented by the present invention.

However, it sometimes occurs a “line defect” during the burn-in test mentioned above. The “line defect” means a problem associated with a test method of the burn-in test and is caused by a defective semiconductor memory device or a failure of contact at an input terminal. During the test of the “on-chip compare” test mode, if one semiconductor memory device (non-target device) is defective and in an abnormal state, both scan signals SCAN of the one semiconductor memory device (non-target device) and other semiconductor memory device (target device) can become “L” when the other semiconductor memory device (target device) is scanned (FIG. 7B). In this case, both output signals of the one semiconductor memory device (non-target device) and the other semiconductor memory device (target device) are mixed and output to the semiconductor test device (not shown) because the output signal lines of the semiconductor memory devices D1 to Dm are commonly connected as shown in FIG. 3. Therefore, the scanned semiconductor memory device (target device) is judged as defective due to the output signal from the one semiconductor memory device (non-target device) even when the target device is not defective.

Accordingly, it is an object of the present invention to prevent a malfunction of a burn-in test caused by a failure of setting a determined test mode due to a “line defect” of the test.

According to one aspect of the present invention, there is provided a semiconductor memory device provided with a logic unit that controls an output of an “on-chip compare” signal indicating pass/fail (pass or fail) of a data which is read from a memory array on the basis of a scan signal at a burn-in test; and a plurality of input terminals for power potential. A specified terminal is selected from a plurality of terminals for power potential provided in the semiconductor memory device for the burn-in test, and the logic unit comprises a control circuit on an input path of the scan signal to control an output of the scan signal on the basis of a signal from the specified terminal.

According to the semiconductor memory device of the present invention, the input path from the specified terminal of the control circuit is preferably branched and electrically connected to a ground potential via a resistance.

According to the semiconductor memory device of the present invention, preferably the logic unit does not output the “on-chip compare” signal as an output signal when the specified terminal is open.

The meritorious effects of the present invention are summarized as follows. The present invention makes it possible to prevent a failure of a burn-in test caused by a malfunction of failure of setting a determined test mode due to a poor contact at the input terminal (e.g., a socket).

### BRIEF DESCRIPTION OF THE DRAWINGS

FIGS. 1A to 1C show schematic structures of a logic unit of a semiconductor memory device of an exemplary embodiment 1 according to the present invention, illustrating; FIG. 1A: circuit diagram; FIG. 1B: truth table of a first control circuit C1; and FIG. 1C: truth table of a second control circuit C2, respectively;

FIGS. 2A and 2B show schematic timing charts of relations of particular signals of semiconductor memory devices of an exemplary embodiment 1 according to the present invention, illustrating; FIG. 2A: normal state; and FIG. 2B: abnormal state, respectively;

FIG. 3 shows a schematic wiring of semiconductor memory devices on a burn-in board according to a conventional art;

FIG. 4 shows a schematic structure of a semiconductor memory device according to a conventional art;

FIGS. 5A and 5B show a schematic structure of a second comparator of a semiconductor memory device according to a conventional art, illustrating; FIG. 5A: circuit diagram; and FIG. 5B: truth table, respectively;

FIGS. 6A and 6B show a schematic structure of a logic unit of a semiconductor memory device according to a conventional art, illustrating; FIG. 6A circuit diagram; and FIG. 6B: truth table, respectively; and

FIGS. 7A and 7B show schematic timing charts of relations of particular signals of semiconductor memory devices according to analysis in a conventional art, illustrating; FIG. 7A in normal state; and FIG. 7B in abnormal state, respectively.

### PREFERRED MODES OF THE INVENTION

### (Exemplary Embodiment 1)

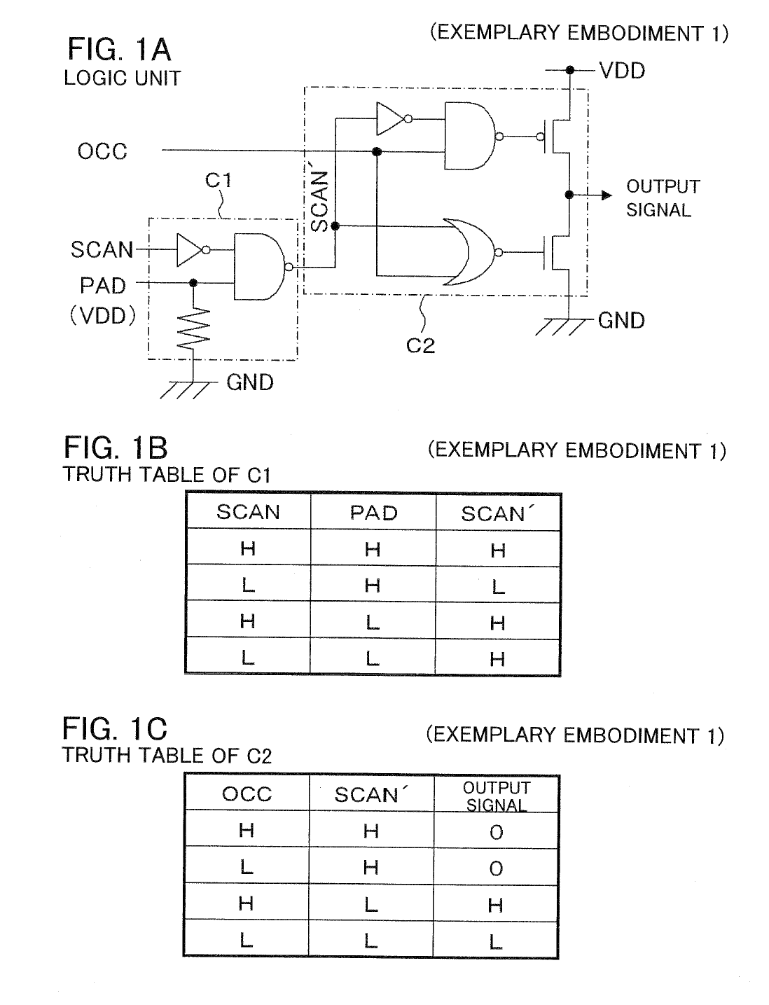

A semiconductor memory device according to an exemplary embodiment 1 is explained with reference to the drawings. FIGS. 1A to 1C show schematic structures of a logic unit of a semiconductor memory device of an exemplary embodiment 1 according to the present invention, illustrating; FIG. 1A: a circuit diagram; FIG. 1B: a truth table of a first control circuit C1; and FIG. 1C: a truth table of a second control circuit C2, respectively.

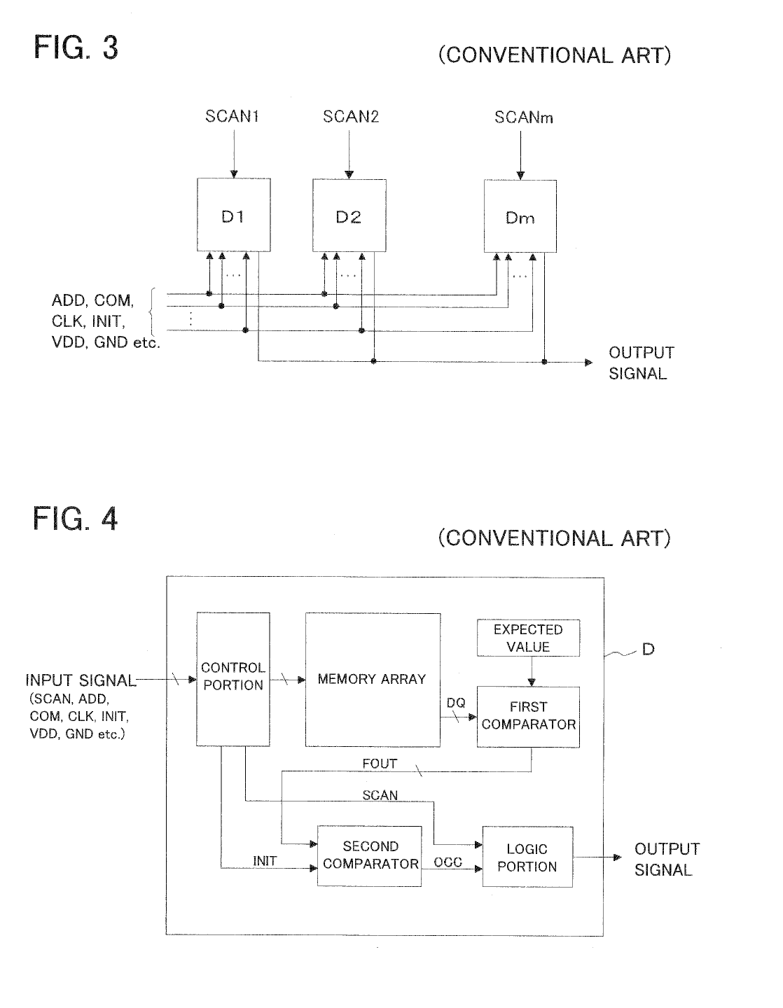

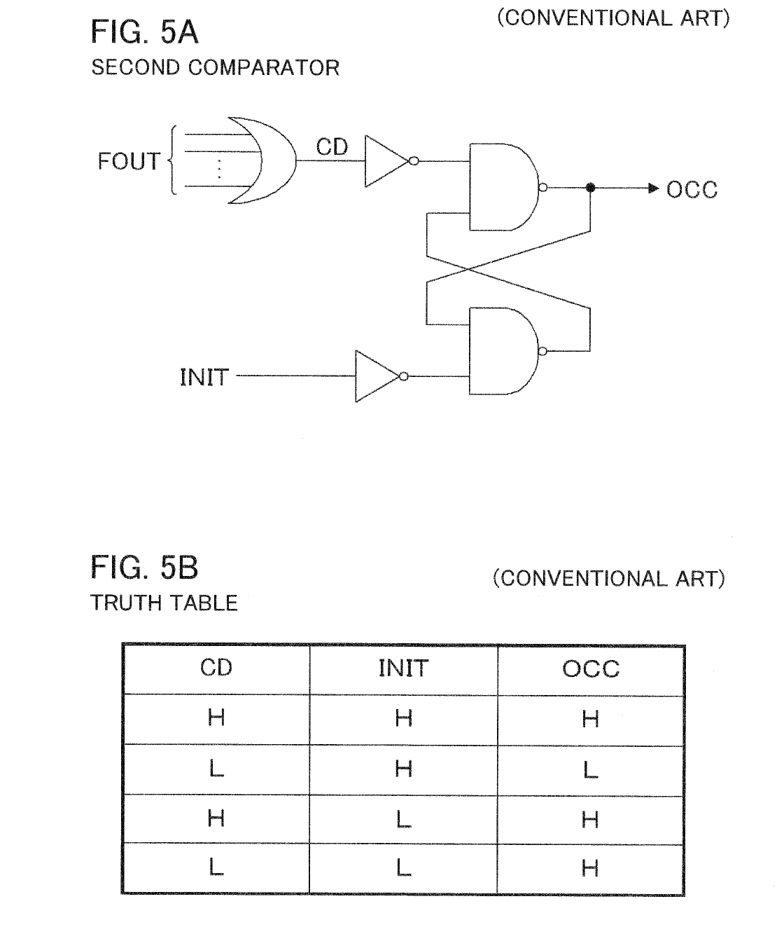

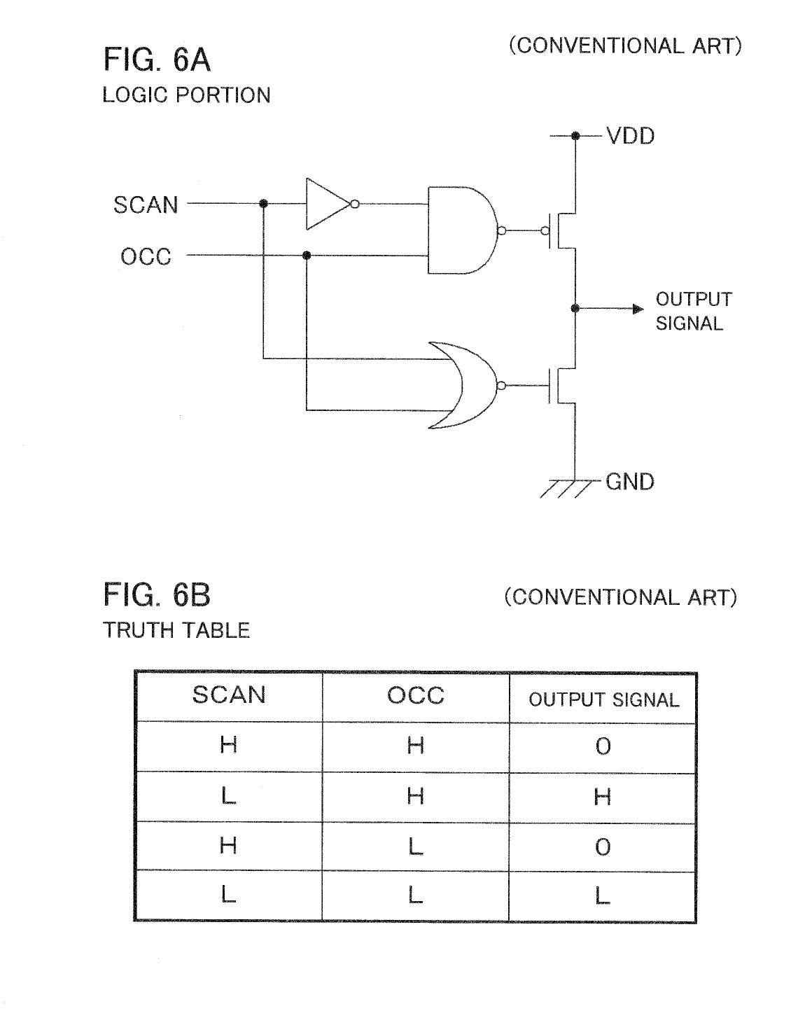

The intended test is performed using one of a plurality of terminals for power potential VDD or one of terminals PADs provided in a semiconductor memory device for the burn-in test to prevent a “line defect” according to the semiconductor memory device of an exemplary embodiment 1. The terminals PADs are used not only for the burn-in test but also in practical use. A first control circuit C1 is provided on an input path of a scan signal SCAN for a second control circuit C2 that may be the same as a conventional circuit (FIGS. 6A and 6B) in a logic unit of the semiconductor memory device in order to make no influence on a defective semiconductor memory device in case of an occurrence of the “line defect” of the semiconductor memory device. A structure other than the logic unit of the semiconductor memory device according to the exemplary embodiment 1 is the same as a conventional structure (FIG. 4). And also a plurality of semiconductor memory devices according to the exemplary embodiment 1 are tested on a burn-in board as a conventional method (FIG. 3).

The first control circuit C1 controls an output of the scan signal SCAN according to the power potential VDD from the terminal PAD. The input path of the terminal PAD of the first control circuit C1 is branched and electrically connected to the ground potential GND via a resistance to eliminate an influence upon another tested semiconductor devices in case of poor contact (OPEN) of the terminal PAD. For example, the first control circuit C1 outputs a control scan signal SCAN′ that is the same state as the scan signal SCAN when an output signal from the terminal PAD is “H” as the result that the power potential VDD is input to the terminal PAD normally (FIG. 1B). Also the first control circuit C1 outputs a control scan signal SCAN′ “H” regardless of the scan signal SCAN when a signal of the terminal PAD is “L” at which the power potential VDD is not input to the terminal PAD due to, for example, poor contact (OPEN) (FIG. 1B). Then the control scan signal SCAN′ “H” is input to a second control circuit C2 and an output signal becomes “0” regardless of an “on-chip compare” signal OCC (FIG. 1C). Therefore, the output signal becomes “0” in the logic circuit when the signal of the terminal PAD is “L” regardless of the scan signal SCAN or the “on-chip compare” signal OCC.

The second control circuit C2 outputs an output signal to a semiconductor test device (not shown) according to the control scan signal SCAN′, the “on-chip compare” signal OCC, the power potential VDD and the ground potential GND.

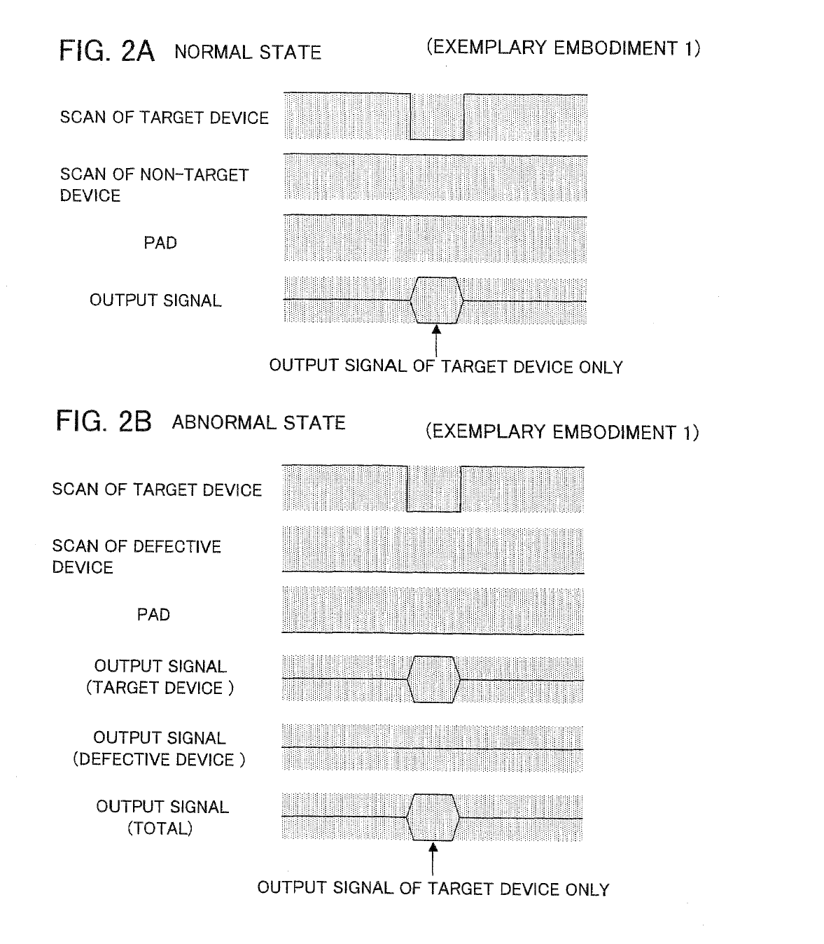

Next, an operation of the semiconductor memory device of the exemplary embodiment 1 according to the present invention is explained with reference to the drawings. FIGS. 2A and 2B show schematic timing charts of relations of particular signals of semiconductor memory devices of an exemplary embodiment 1 according to the present invention, illustrating; FIG. 2A: normal state; and FIG. 2B: abnormal state, respectively.

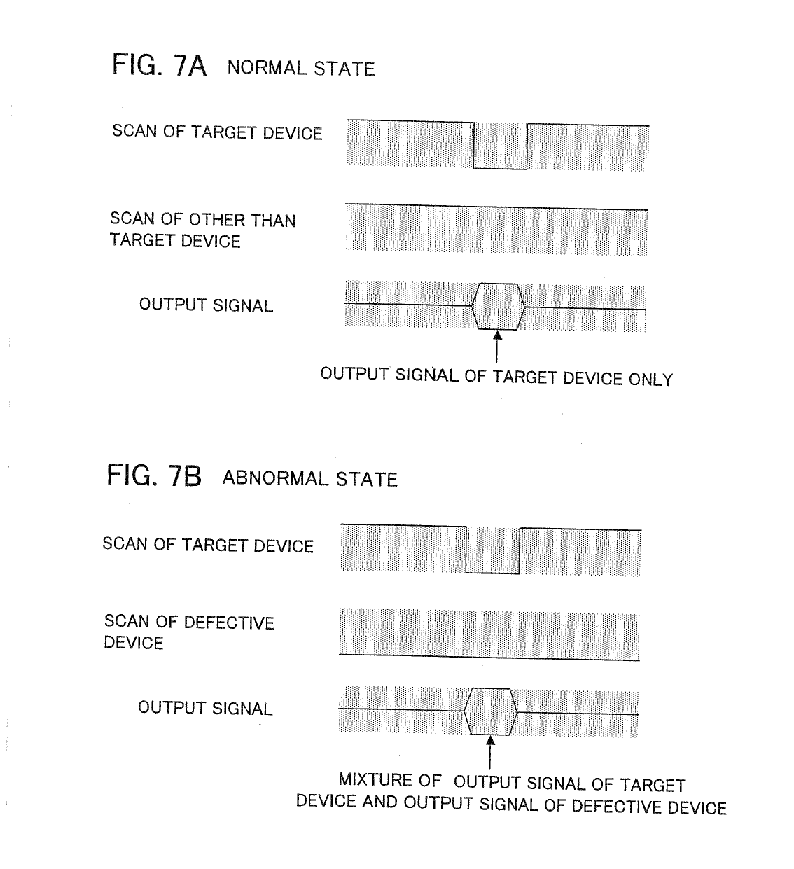

At a normal state (FIG. 2A), the signal of the terminal PAD is “H” and an output signal of a target semiconductor memory device (target device) only is output by setting the scan signal SCAN of the target semiconductor memory device (target device) “L” leaving a scan signal of a non-target semiconductor memory device (non-target device) as “H”. This is the same operation as the conventional art (FIG. 7A).

At an abnormal state (FIG. 2B), when the signal of the terminal PAD of a defective semiconductor memory device (defective device) is “L”, it is deemed that there was an abnormal occurrence in the defective semiconductor memory device (defective device) and the control scan signal SCAN′ of the defective semiconductor memory device (defective device) becomes “H” even when the scan signal SCAN of the defective semiconductor memory device (defective device) is “L” (FIG. 1B), then an output signal of the defective semiconductor memory device (defective device) becomes “0” (FIG. 1C). Under such conditions, an output signal of the target semiconductor memory device (target device) only is output by setting a scan signal SCAN of the target semiconductor memory device (target device) “L”. An abnormal signal of the output signal of the defective semiconductor memory device (defective device) is not output in this way.

According to an exemplary embodiment 1, it becomes possible to prevent a good semiconductor memory device from being judged as a defective device caused by another defective semiconductor memory device during a burn-in test. Therefore, a conforming ratio of semiconductor memory devices is improved and then the yield is improved.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modification aforementioned.

What is claimed is:

1. A semiconductor memory device comprising:
a logic unit that controls an output of an “on-chip compare” signal indicating pass/fail of a data that is read from a memory array on the basis of a scan signal upon a burn-in test; and
a plurality of input terminals for power potential; wherein
a specified terminal is selected from said plurality of terminals for power potential for said burn-in test; and
said logic unit comprises a control circuit on an input path of said scan signal to control an output of said scan signal on the basis of a signal from said specified terminal.

2. The semiconductor memory device as defined in claim 1, wherein said input path from said specified terminal of said control circuit is branched and electrically connected to a ground potential via a resistance.

3. The semiconductor memory device as defined in claim 1, wherein said logic unit does not output said “on-chip compare” signal as an output signal when said specified terminal is open.

4. The semiconductor memory device as defined in claim 2, wherein said logic unit does not output said “on-chip compare” signal as an output signal when said specified terminal is open.

5. The semiconductor memory device as defined in claim 1, wherein said control circuit has an input terminal for the scan signal termed “SCAN” and said input path termed “PAD” as input signals, respectively, and an output signal termed “SCAN′” supplied to said logic unit;
said logic unit being controlled by said output signal SCAN′ of said control circuit and another control signal termed “OCC”;
said control circuit being controlled under Truth Table 1 as follows:
TRUTH TABLE 1

| SCAN | PAD | SCAN′ |
|---|---|---|
| H | H | H |
| L | H | L |
| H | L | H |
| L | L | H |

said logic unit being controlled under Truth Table 2 as follows:
TRUTH TABLE 2

| | | OUTPUT |
|---|---|---|
| OCC | SCAN′ | SIGNAL |
| H | H | O |
| L | H | O |
| H | L | H |
| L | L | L |

where “OUTPUT SIGNAL” represents the output signal of the control circuit.
